(19) United States
(12) Patent Application Publication
(10) Pub. No.: US 2015/0279737 A1
(43) Pub. Date: Oct. 1, 2015

(54) METHOD FOR PREPARING SILICIDE OF A SEMICONDUCTOR DEVICE AND A SOURCE/DRAIN FOR USE IN THE SEMICONDUCTOR DEVICE

(71) Applicant: Research & Business Foundation SUNGKYUNKWAN UNIVERSITY, Suwon-si (KR)

(72) Inventors: Hoojeong LEE, Suwon-si (KR); Sekwon NA, Seoul (KR); Jun Gu KANG, Seoul (KR)

(73) Assignee: Research & Business Foundation SUNGKYUNKWAN UNIVERSITY, Suwon-si (KR)

(21) Appl. No.: 14/670,995

(22) Filed: Mar. 27, 2015

(30) Foreign Application Priority Data
Mar. 27, 2014 (KR) 10-2014-0036232

(51) Int. Cl. H01L 21/768; H01L 29/45; H01L 21/285

(52) U.S. Cl. CPC H01L 21/76889; H01L 21/2855; H01L 29/45

(57) ABSTRACT

Provided herein is a method for forming silicide of a semiconductor device and a source/drain for use in the semiconductor device, the method including preparing a silicon substrate that includes silicon; depositing ytterbium, refractory metal and transition metal nitride on the silicon substrate so that the ytterbium and the refractory metal form an ytterbium alloy thin film and the transition metal nitride form a capping layer; and heating the silicon substrate to form ytterbium silicide on an interface between the silicon substrate and the ytterbium alloy thin film.

### CROSS-REFERENCE TO RELATED APPLICATION

This application claims the benefit of priority under 35 U.S.C. §119(a) of Korean Patent Application No. 10-2014-0036232, filed on Mar. 27, 2014, in the Korean Intellectual Property Office, the entire disclosure of which is incorporated herein by reference for all purposes.

### FIELD

Various embodiments of the present invention relate to a method for preparing silicide of a semiconductor device and a source/drain for use in the semiconductor device, and more particularly, to a method for preparing silicide stably even at a high temperature by adopting a refractory metal layer so as to form a semiconductor device having excellent heat stability, and a source/drain for use in the semiconductor device.

### BACKGROUND

Silicide is an intermediate phase substance wherein silicon and transition metal are combined at a quantitative chemical ratio. Silicide is widely used in semiconductor processes in order to reduce the contact resistance of semiconductor devices.

Specifically, silicide is formed selectively on a source, drain and gate in a CMOS (complementary metal-oxide semiconductor) process, so as to prevent a spiking phenomenon from occurring due to diffusion with a wiring layer.

Furthermore, in an electrical perspective, silicide forms an ohmic contact to reduce the contact resistance of a semiconductor device, thereby improving the RC delay effect. In a processing perspective, silicide may function as an ILD (inter layer dielectric) layer for connecting a TFT and a metal wiring layer, and as an etch-stopping layer for resolving the difference of heights between a gate, source and drain, in dry etching.

As it became possible to manufacture high density semiconductor devices with increasingly smaller size, the process of preparing silicide has become an important part in manufacturing semiconductor devices.

Silicide of various phases can be formed depending on the type of metal and the bond energy in the bonding between the metal and silicon. Various types of such silicide include tantalum silicide (TaSi₂), molybdenum silicide (MoSi₂), tungsten silicide (WSi₂), titanium silicide (TiSi₂), and iron silicide (FeSi₂) and so forth.

Of the various types of silicides, titanium silicide (TiSi₂) is most widely used in the salicide process of logic elements, and tungsten silicide (WSi₂) is being used in gate regions of DRAM which is a memory device. However, processing of ultrafine devices of which the design rule is 0.18 μm or less requires new types of silicide substance and processes.

Furthermore, conventional types of silicide react intensely with silicon which may be the substrate of a source or drain when preparing silicide, thereby preventing the silicide from growing epitaxially, and deteriorating the interface between the semiconductor substrate and silicide, which leads to formation of high Schottky barriers at high temperatures.

Therefore, research needs to be conducted on a method for forming silicide with improved heat stability that may be applied to ultrafine devices so as to manufacture a source and drain having how Schottky barriers.

### PRIOR ART DOCUMENTS

### Patent Literature

(Patent document 1) Korean patent publication no. 10-1997-0077070
(Patent document 2) Korean patent publication no. 10-2001-0062922

### SUMMARY

Therefore, a purpose of various embodiments of the present disclosure is to resolve the aforementioned problems of conventional technology, that is, to provide a method for forming silicide of a semiconductor device, the method being capable of stably forming ytterbium silicide grown epitaxially and having a low Schottky barrier even at high temperatures.

Another purpose of various embodiments of the present disclosure is to provide a source and drain for use in a semiconductor device, the source and drain being capable of reducing a contact resistance of the device by stably forming ytterbium silicide grown epitaxially at high temperatures.

An embodiment of the present disclosure provides a method for forming silicide of a semiconductor device, the method including preparing a silicon substrate that includes silicon; depositing ytterbium, refractory metal and transition metal nitride on the silicon substrate so that the ytterbium and the refractory metal form an ytterbium alloy thin film and the transition metal nitride form a capping layer; and heating the silicon substrate to form ytterbium silicide on an interface between the silicon substrate and the ytterbium alloy thin film.

The depositing of ytterbium, refractory metal and transition metal nitride may be performed by RF magnetron sputtering.

An RF power for the refractory metal may be between 20 and 100 W.

In response to the RF power for the refractory metal being 30 W, the refractory metal may be between 2 and 8 parts by weight for every 100 parts by weight of the ytterbium.

In response to the RF power for the refractory metal being 60 W, the refractory metal may be between 17 and 23 parts by weight for every 100 parts by weight of the ytterbium.

The heating may be heating by a rapid thermal annealing method under an atmospheric temperature of between 300 and 800° C.

The heating may make the ytterbium and the silicon in the silicon substrate react so that the ytterbium silicide is formed while the refractory metal is concentrated to an upper part of the ytterbium alloy thin film so that a refractory metal layer is formed that includes the refractory metal.

The refractory metal layer may be formed on an upper part of the ytterbium silicide so that the ytterbium silicide may be grown epitaxially.

The refractory metal layer may have an amorphous shape where at least two of the ytterbium, refractory metal and silicon are mixed.

Another embodiment of the present disclosure provides a source/drain for use in a semiconductor device, the source/drain including a silicon substrate; an ytterbium silicide layer formed on the silicon substrate and including ytterbium silicide; and a refractory metal layer formed on the ytterbium silicide layer and including the refractory metal.

The refractory metal may be selected from niobium (Nb), molybdenum (Mo), tantalum (Ta), and tungsten (W), and a combination thereof.

The refractory metal layer may be amorphous.

The source/drain may further include a capping layer formed on the refractory metal layer, and including transition metal nitride.

The transition metal of the transition metal nitride may be selected from titanium (Ti), zinc (Zn), hafnium (Hf), vanadium (V), niobium (Nb), tantalum (Ta), chrome (Cr), molybdenum (Mo), tungsten (W), iron (Fe), cobalt (Co), rhodium (Rh), palladium (Pd), platinum (Pt), copper (Cu), and aluminum (Al), and a combination thereof.

By co-depositing the ytterbium and refractory metal and heating the same, the refractory metal layer formed as the refractory metal is shoved to the upper part prevents oxidation of the ytterbium at a high temperature, and delays the reaction between the ytterbium and the silicon, thereby stably forming ytterbium silicide grown epitaxially.

By forming the ytterbium silicide grown epitaxially, Schottky barriers may be lowered, thereby realizing a source and drain having a reduced contact resistance between the ytterbium silicide and the device.

The source and drain having a low Schottky barrier may be easily applied to the semiconductor field including transistors.

The aforementioned effects of the present invention are not limited to the aforementioned effects, and other effects not mentioned above will be clearly understood by those skilled in the art from the disclosure of the claims.

### BRIEF DESCRIPTION OF THE DRAWINGS

FIG. 1 is a flowchart sequentially illustrating a method for forming silicide of a semiconductor device according to an embodiment of the present disclosure.

FIG. 2 is a graph illustrating a result of an x-ray diffraction analysis for a phase analysis on the ytterbium silicide formed by the method of embodiment 1.

FIG. 3 is a graph illustrating a result of an x-ray diffraction analysis for a phase analysis on the ytterbium silicide formed by the method of embodiment 2.

FIG. 4 is a graph illustrating a result of an x-ray diffraction analysis for a phase analysis on the ytterbium silicide formed by the method of comparative example 1.

FIG. 5 is an image of the ytterbium silicide formed by the method of embodiment 1 analyzed by a transmission electron microscope.

FIG. 6 is an image of the ytterbium silicide formed by the method of embodiment 2 analyzed by the transmission electron microscope.

FIG. 7 is an image of the ytterbium silicide formed by the method of embodiment 3 analyzed by the transmission electron microscope.

FIG. 8 is an image of the ytterbium silicide formed by the method of comparative example 1 analyzed by the transmission electron microscope.

FIG. 9 is a graph of I-V of a circular diode measured in order to observe Schottky barrier heights (SBH) of the ytterbium silicide formed by the methods of embodiments 1 and 2, and comparative example 1.

FIG. 10 is a graph of contact resistances of the ytterbium silicide formed by the methods of embodiments 1 and 2, and comparative example 1.

### DETAILED DESCRIPTION

The following detailed description is provided to assist the reader in gaining a comprehensive understanding of the methods, apparatuses, and/or systems described herein. Accordingly, various changes, modifications, and equivalents of the systems, apparatuses and/or methods described herein will be suggested to those of ordinary skill in the art. Also, descriptions of well-known functions and constructions may be omitted for increased clarity and conciseness.

Furthermore, a singular form may include a plural from as long as it is not specifically mentioned in a sentence. Furthermore, “include/comprise” or “including/comprising” used in the specification represents that one or more components, steps, operations, and elements exist or are added.

Furthermore, unless defined otherwise, all the terms used in this specification including technical and scientific terms have the same meanings as would be generally understood by those skilled in the related art. The terms defined in generally used dictionaries should be construed as having the same meanings as would be construed in the context of the related art, and unless clearly defined otherwise in this specification, should not be construed as having idealistic or overly formal meanings.

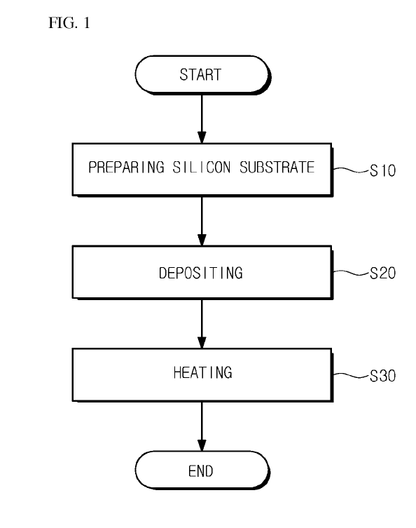

Hereinafter, a method for forming silicide of a semiconductor device according to an embodiment of the present disclosure will be explained with reference to FIG. 1.

The method for forming silicide of a semiconductor device includes preparing a silicon substrate (S10), depositing (S20), and heating (S30).

The preparing a silicon substrate (S10) is a step of preparing a silicon substrate that is a subject of forming silicide.

The silicon substrate may be a semiconductor wafer having a silicon portion on its surface.

Ytterbium silicide (YbSi₂) may have a low Schottky barrier height to n-type silicon, and thus it is desirable to prepare n-type silicon.

The depositing (S20) is a step of depositing ytterbium (Yb), refractory metal, and transition metal nitride on the silicon substrate. Through the depositing (S20), the ytterbium and refractory metal may form an ytterbium alloy thin film, while the transition metal nitride forms a capping layer.

Ytterbium (Yb) has a low specific resistance when forming silicide, and it does not deteriorate even on silicon of an ultrafine pattern. It also has excellent heat stability and chemical stability, and a small difference of lattice constant from silicone, and may thus form a very stable silicide.

Herein, refractory metal is a general term used for metal having a high melting point of 2000° C. or above. In the present disclosure, niobium (Nb), molybdenum (Mo), tantalum (Ta) or tungsten (W), or a combination thereof may be used as refractory metal, but desirably, molybdenum (Mo) may be used.

An ytterbium alloy thin film may be formed by co-depositing ytterbium and refractory metal on the silicon substrate using the RF magnetron sputtering method in a high vacuum. Herein, the ytterbium alloy thin film may have a thickness of between 10 and 80 nm, and desirably between 15 and 50 nm.

RF power for the refractory metal may be between 20 and 10 W, and desirably between 30 and 90 W.

Contents of ytterbium and refractory metal may differ depending on a degree of RF power for the refractory metal. Specifically, when the RF power for the refractory metal is 30 W, the refractory metal may be between 2 and 8 parts by weight for every 100 parts by weight of the ytterbium, and when the RF power for the refractory metal is 60 W, the refractory metal may be between 17 and 23 parts by weight for every 100 parts by weight of the ytterbium.

When the content of the refractory metal is outside the aforementioned range, ytterbium silicide may not be grown epitaxially, or the ytterbium may be oxidized.

In order to prevent the ytterbium from being oxidized as much as possible, ytterbium, refractory metal and transition metal nitride may be co-deposited in a high vacuum chamber.

The transition metal of the transition metal nitride may be titanium (Ti), zinc (Zn), hafnium (Hf), vanadium (V), niobium (Nb), tantalum (Ta), chrome (Cr), molybdenum (Mo), tungsten (W), iron (Fe), cobalt (Co), rhodium (Rh), palladium (Pd), platinum (Pt), copper (Cu), or aluminum (Al), or sometimes, a combination thereof.

Tantalum nitride that has an excellent effect of preventing oxidation of ytterbium may desirably be used.

A capping layer may have a thickness of between 20 and 100 nm, and desirably between 25 and 70 nm.

Ytterbium is easily oxidized to form ytterbium oxide, and since the ytterbium oxide interrupts the formation of ytterbium silicide grown epitaxially, a capping layer made of a transition metal nitride may take the role of preventing the ytterbium from oxidizing.

The heating (S30) is a step of heating the silicon substrate where the ytterbium alloy thin film and capping layer are formed by the depositing (S20), so as to form ytterbium silicide.

The heating (S30) may be performed by a rapid thermal annealing under an atmospheric temperature of between 300 and 800° C.

When the temperature of the heating is or below 300° C., ytterbium silicide cannot be grown epitaxially, and when the temperature of the heating is above 800° C., the silicon of the silicon substrate may react with the refractory metal and form silicide, making it difficult to form ytterbium silicide.

Specifically, the rapid thermal annealing may deliver heat to the silicon substrate by a method of using radiant rays of a tungsten halogen lamp. The rapid thermal annealing is advantageous in that various parameters such as pressures of various gases and rapid change of temperature inside a processing chamber may be controlled easily, and that the temperature of the silicon substrate where the ytterbium alloy thin film and capping layer are formed can be raised within a short period of time.

Since ytterbium has a higher reactivity with silicon in the silicon substrate than the refractory metal, when the heating (C30) is performed, the ytterbium and the silicon in the silicon substrate would react and form ytterbium silicide on an interface of the thin film and the substrate.

Herein, as the refractory metal distributed along the ytterbium alloy thin film is shoved to an upper part of the ytterbium alloy thin film due to the formation of the ytterbium silicide, a refractory metal layer having a relatively higher concentration of refractory metal is formed.

The refractory metal layer may have an amorphous shape where at least two of ytterbium, refractory metal and silicon are mixed.

Since the ytterbium alloy thin film and capping layer in the refractory metal layer were heated, the refractory metal layer formed on the upper part of the ytterbium alloy thin film prevents the ytterbium from oxidizing, thereby maximizing the effect of preventing the ytterbium from oxidizing together with the capping layer.

Furthermore, the refractory metal that was distributed along the ytterbium alloy thin film delays the reaction between the ytterbium and silicon, thereby keeping the interface between the ytterbium silicide and the silicon substrate flat, providing a low Schottky barrier.

That is, the formation of the refractory metal layer provides a conformity interface between the ytterbium silicide and the silicon, and allows the ytterbium silicide to grow epitaxially, free of internal defects, which leads to forming a low Schottky barrier with the silicon substrate.

A source/drain for a semiconductor device according to an embodiment of the present disclosure may be prepared by the aforementioned method for forming a silicide of a semiconductor device, and may include a silicon substrate, an ytterbium silicide layer formed on the silicon substrate and including ytterbium silicide, and a refractory metal layer formed on the ytterbium silicide layer and including refractory metal.

Furthermore, the source/drain may further include a capping layer formed on the refractory metal layer and including transition metal nitride.

The refractory metal layer and capping layer may take a role of preventing oxidation of the ytterbium

Explanation on each of the silicon substrate, ytterbium silicide layer, refractory metal layer, and capping layer is the same as in the aforementioned method for forming a silicide of a semiconductor device.

Hereinafter, results of tests conducted to prove the excellent effects of the method for forming silicide according to the present disclosure will be presented.

### Embodiment 1

An ytterbium-molybdenum alloy thin film and capping layer were formed by co-depositing ytterbium, molybdenum, and tantalum nitride on a silicon substrate in a high vacuum chamber by the RF magnetron sputtering method. Herein, the RF power for the molybdenum was 30 W. After the co-depositing, the silicon substrate was subjected to a rapid thermal annealing at temperatures of 300° C., 350° C., 400° C., 450° C., 500° C., 600° C., and 700° C. under a nitrogen atmosphere, and as a result, ytterbium silicide was formed.

### Embodiment 2

An ytterbium-molybdenum alloy thin film and capping layer were formed by co-depositing ytterbium, molybdenum, and tantalum nitride on a silicon substrate in a high vacuum chamber by the RF magnetron sputtering method. Herein, the RF power for the molybdenum was 60 W. After the co-depositing, the silicon substrate was subjected to a rapid thermal annealing at temperatures of 300° C., 350° C., 400° C., 450° C., 500° C., 600° C., and 700° C. under a nitrogen atmosphere, and as a result, ytterbium silicide was formed.

### Embodiment 3

An ytterbium-molybdenum alloy thin film and capping layer were formed by co-depositing ytterbium, molybdenum, and tantalum nitride on a silicon substrate in a high vacuum chamber by the RF magnetron sputtering method. Herein, the RF power for the molybdenum was 90 W. After the co-depositing, the silicon substrate was subjected to a rapid thermal annealing at temperatures of 300° C., 350° C., 400° C., 450° C., 500° C., 600° C., 700° C., and 750° C. under a nitrogen atmosphere, and as a result, ytterbium silicide was formed.

### COMPARATIVE EXAMPLE 1

Ytterbium and tantalum nitride were co-deposited on a silicon substrate in a high vacuum chamber by the RF magnetron sputtering method, and then the silicon substrate formed was subjected to a rapid thermal annealing at temperatures of 300° C., 350° C., 400° C., 450° C., 500° C., 600° C., and 700° C., under a nitrogen atmosphere, and as a result, ytterbium silicide was formed.

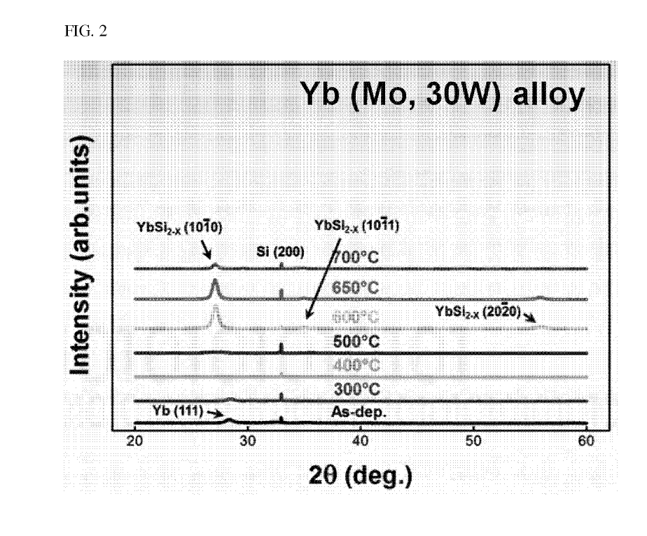

The ytterbium silicide formed by the methods of embodiments 1 and 2, and comparative example 1 was subjected to x-ray diffraction analysis for phase analysis on the ytterbium silicide. An x-ray analysis was conducted on each ytterbium silicide formed at each of the aforementioned temperatures, and the results were as shown in FIGS. 2 to 4.

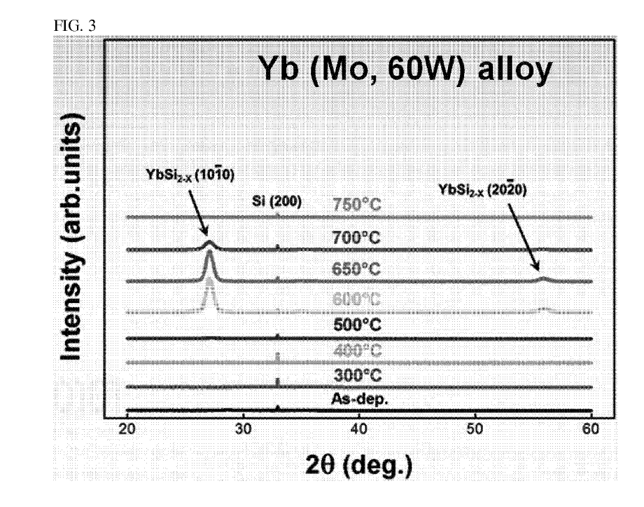

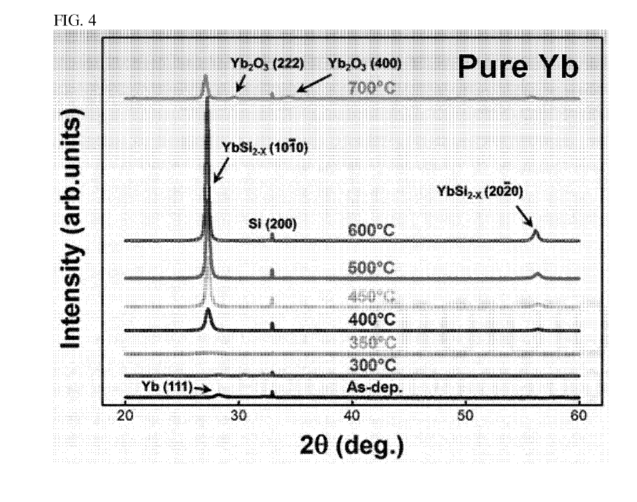

One can see that oxidized ytterbium (Yb₂O₃) reached its peak in FIG. 4, unlike in FIGS. 2 and 3. This shows that co-depositing molybdenum, which is a type of refractory metal, together with ytterbium, and then forming ytterbium silicide by heating shoves molybdenum to the upper part of the thin film, thereby forming a refractory metal layer at a high temperature, and thus preventing the ytterbium from oxidizing.

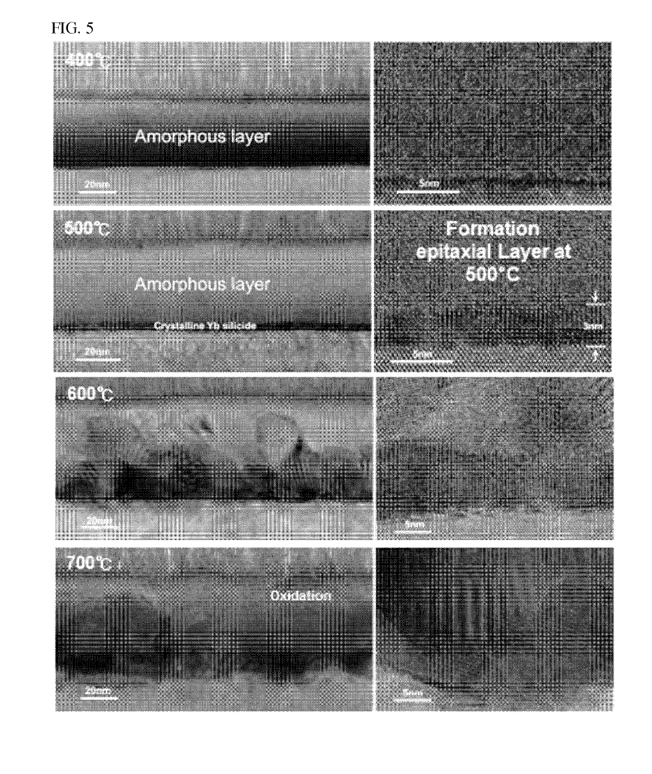

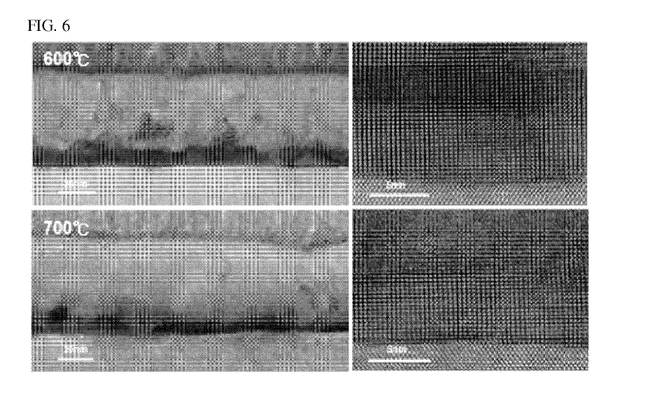

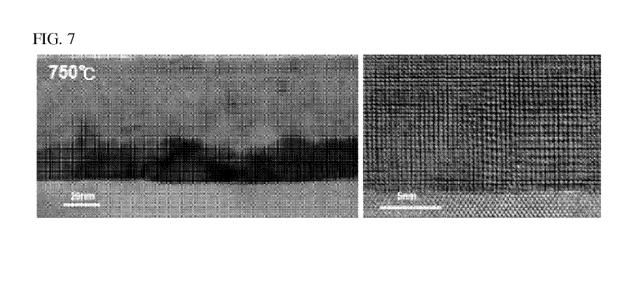

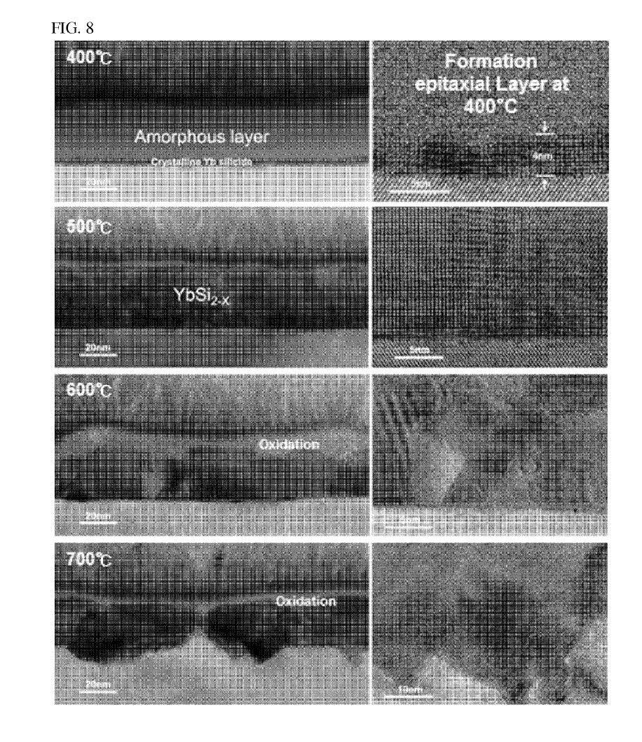

In order to see whether or not the ytterbium silicide formed by the methods of embodiments 1 to 3, and comparative example 1 have grown epitaxially, a transmission electron microscopy analysis was conducted on each ytterbium silicide. A transmission electron microscopy analysis was conducted on each of the ytterbium silicide formed at each of the aforementioned temperatures, and the results were as shown in FIGS. 5 to 8.

FIGS. 5 to 8 show that ytterbium silicide is epitaxially formed at a higher temperature than in FIG. 4.

Especially, in embodiment 1, ytterbium silicide was epitaxially formed at 500° C. and 600° C.; in embodiment 2, ytterbium silicide was epitaxially formed at heating temperatures of 600° C. and 700° C.; and in embodiment 3, ytterbium silicide was epitaxially formed at 750° C. On the other hand, in comparative example 1, ytterbium silicide was epitaxially formed at 400° C. only, and no epitaxial formation was observed above that temperature.

That is, one could see that by co-depositing refractory metal together with ytterbium provides a conformity interface between the ytterbium silicide and silicon, and allows the ytterbium silicide to grow in a stable and consistent arrangement without any coupling occurring inside.

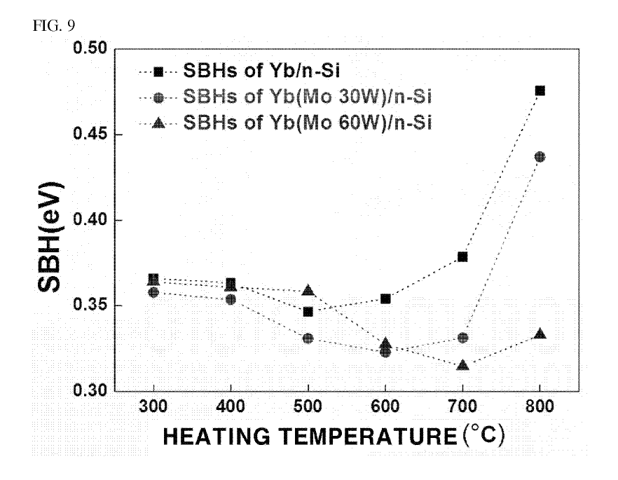

To observe the Schottky barrier height (SBH) of the ytterbium silicide formed by methods of embodiments 1 to 2, and comparative example 1, a circular diode was prepared having a diameter of 50 μm using the methods of embodiments 1 to 2, and comparative example 1, and I-V was measured, and the results are as shown in FIG. 9. Furthermore, table 1 below shows a comparison between embodiment 1 and comparative example 1.

TABLE 1

| | | Heating | | | | | |
|---|---|---|---|---|---|---|---|
| | | temperature (° C.) | | | | | |
| | | 300 | 400 | 500 | 600 | 700 | 800 |
| Embodiment 1 | SBH (eV) | 0.366 | 0.363 | 0.347 | 0.354 | 0.379 | 0.476 |
| Comparative | SBH (eV) | 0.358 | 0.354 | 0.331 | 0.323 | 0.331 | 0.437 |
| example 1 | | | | | | | |

According to FIG. 9 and table 1, when heated at a high temperature of above 500° C., the diodes prepared by embodiments 1 and 2 had lower Schottky barriers than comparative example 1.

This shows that molybdenum that is the refractory metal distributed over the thin film delayed the reaction between the ytterbium and silicon, thereby keeping the interface between the ytterbium silicide and silicon substrate flat and thus providing a low Schottky barrier.

One could also see that when the RF power for molybdenum was 60 W as compared to 30 W, the effect of delaying the reaction was greater, that is, the more the amount of alloy in the molybdenum, the greater the effect of delaying reaction.

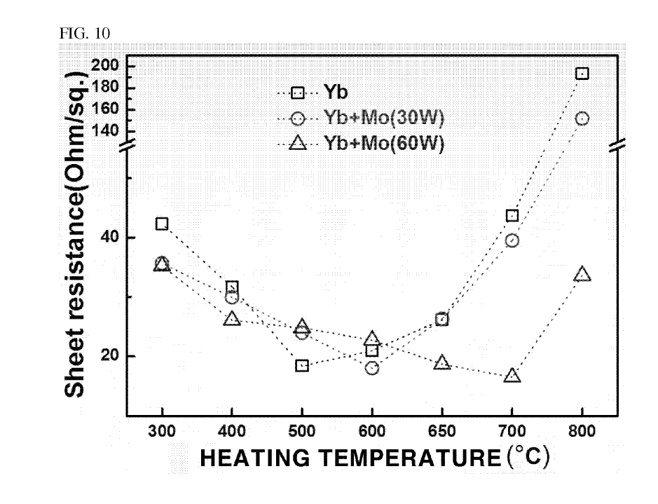

In order to observe the contact resistance of the ytterbium silicide formed by the methods of embodiments 1 and 2, and comparative example 1, a circular diode was prepared having a diameter of 50 μm using the methods of embodiments 1 to 2, and comparative example 1, and sheet resistances were measured. The results are as shown in FIG. 10.

According to FIG. 10, when the RF power for molybdenum was 30 W and the heating was performed at 600° C., the sheet resistance decreased to 18.0Ω (embodiment 1), and when the RF power for molybdenum was 60 W, the sheet resistance decreased to 16.5Ω even when the heating was performed at 700° C. (embodiment 2). On the other hand, comparative example 1 wherein only ytterbium was deposited, the sheet resistance was 20Ω even when heating was performed at 500° C.

Based on the aforementioned, one could see that according to embodiments 1 and 2, it is possible to form ytterbium silicide grown epitaxially and having a low Schottky barrier even at high temperatures, thereby preparing a source and drain having a low contact resistance.

While this invention has been described in connection with what is presently considered to be practical embodiments, it is to be understood that the invention is not limited to the disclosed embodiments, but, on the contrary, is intended to cover various modifications and equivalent arrangements included within the spirit and scope of the appended claims. Therefore, the aforementioned embodiments should be understood to be exemplary but not limiting the present invention in any way.

What is claimed is:

1. A method for forming silicide of a semiconductor device, the method comprising:
preparing a silicon substrate that includes silicon;
depositing ytterbium, refractory metal and transition metal nitride on the silicon substrate so that the ytterbium and the refractory metal form an ytterbium alloy thin film and the transition metal nitride form a capping layer; and
heating the silicon substrate to form ytterbium silicide on an interface between the silicon substrate and the ytterbium alloy thin film.

2. The method according to claim 1,
wherein the depositing of ytterbium, refractory metal and transition metal nitride is performed by RF magnetron sputtering.

3. The method according to claim 2,
wherein an RF power for the refractory metal is between 20 and 100 W.

4. The method according to claim 3,
wherein, in response to the RF power for the refractory metal being 30 W, the refractory metal is between 2 and 8 parts by weight for every 100 parts by weight of the ytterbium.

5. The method according to claim 3,
wherein, in response to the RF power for the refractory metal being 60 W, the refractory metal is between 17 and 23 parts by weight for every 100 parts by weight of the ytterbium.

6. The method according to claim 1,
wherein the heating is heating by a rapid thermal annealing method under an atmospheric temperature of between 300 and 800 .

7. The method according to claim 1,
wherein the heating makes the ytterbium and the silicon in the silicon substrate react so that the ytterbium silicide is formed while the refractory metal is concentrated to an upper part of the ytterbium alloy thin film so that a refractory metal layer is formed that includes the refractory metal.

8. The method according to claim 7,
wherein the refractory metal layer is formed on an upper part of the ytterbium silicide so that the ytterbium silicide may be grown epitaxially.

9. The method according to claim 7,
wherein the refractory metal layer may have an amorphous shape where at least two of the ytterbium, refractory metal and silicon are mixed.

10. A source/drain for use in a semiconductor device, the source/drain comprising:
a silicon substrate;
an ytterbium silicide layer formed on the silicon substrate and including ytterbium silicide; and
a refractory metal layer formed on the ytterbium silicide layer and including the refractory metal.

11. The source/drain according to claim 10,
wherein the refractory metal is selected from niobium (Nb), molybdenum (Mo), tantalum (Ta), and tungsten (W), and a combination thereof.

12. The source/drain according to claim 10,
wherein the refractory metal layer is amorphous.

13. The source/drain according to claim 10,
further comprising a capping layer formed on the refractory metal layer, and including transition metal nitride.

14. The source/drain according to claim 13,
wherein the transition metal of the transition metal nitride is selected from titanium (Ti), zinc (Zn), hafnium (Hf), vanadium (V), niobium (Nb), tantalum (Ta), chrome (Cr), molybdenum (Mo), tungsten (W), iron (Fe), cobalt (Co), rhodium (Rh), palladium (Pd), platinum (Pt), copper (Cu), and aluminum (Al), and a combination thereof.
